(19) United States
(12) Patent Application Publication
(10) Pub. No.: US 2025/0260400 A1
(43) Pub. Date: Aug. 14, 2025

(54) INPUT DEVICE

(71) Applicant: Panasonic Intellectual Property Management Co., Ltd., Osaka (JP)

(72) Inventors: Ryo NAKAE, Okayama (JP); Yasunori YANAI, Okayama (JP); Naoki TANAKA, Okayama (JP); Takehiko NARA, Okayama (JP); Masao NAGASE, Okayama (JP); Masafumi OGAWA, Okayama (JP)

(21) Appl. No.: 18/857,082

(22) PCT Filed: Apr. 10, 2023
(86) PCT No.: PCT/JP2023/014484

§ 371 Date: Oct. 15, 2024

(30) Foreign Application Priority Data
Apr. 21, 2022 (JP) 2022-070324

(51) Int. Cl. H03K 17/96

(52) U.S. Cl. CPC H03K 17/962; H03K 2217/9607

(57) ABSTRACT

An input device includes a fixed electrode layer, an elastic body, a movable member, and an insulating layer. The movable member includes a pressure receiving part on which an operation force is to be exerted. The elastic body includes a first deformable part and at least one second deformable part. When the operation force is exerted on the pressure receiving part, the first deformable part and the at least one second deformable part are compressed. At least at a time point at which the operation force is started to be exerted on the pressure receiving part, a ratio of change in an area of the first deformable part is higher than a ratio of change in an area of the at least one second deformable part.

### TECHNICAL FIELD

The present disclosure generally relates to input devices and specifically relates to an input device including an electrically conductive elastic body.

### BACKGROUND ART

Patent Literature 1 describes an input device including an operating member (movable member) and a plurality of capacitive pressure sensors. Each of the plurality of pressure sensors includes electrodes, a pressing part, an insulator, and an elastic body. The insulator and the elastic body are disposed between the pressing part and the electrodes. When the elastic body is pressed by the pressing part, a plurality of projections of the elastic body are crushed. This increases an area where the elastic body and the insulator are in contact with each other, and the capacitance of the pressure sensor thus increases.

In the input device described in Patent Literature 1, however, the plurality of projections are crushed when a force of a pressing operation (an operation force) is small, which may drastically change the capacitance of the pressure sensor. Therefore, in the input device described in Patent Literature 1, the characteristic of the capacitance with respect to the operation force may not meet a required level.

### CITATION LIST

### Patent Literature

Patent Literature 1: WO 2019/230517 A1

### SUMMARY OF INVENTION

An object of the present disclosure is to provide an input device configured to suppress capacitance from drastically changing when an operation force is relatively small.

An input device according to an aspect of the present disclosure includes a fixed electrode layer, an elastic body, a movable member, and an insulating layer. The fixed electrode layer includes a first fixed electrode and a second fixed electrode electrically insulated from the first fixed electrode. The elastic body is electrically conductive. The elastic body has a counter surface facing the first fixed electrode and the second fixed electrode in a predetermined direction. The movable member includes a pressure receiving part on which an operation force is to be exerted. A movable member is configured to push the elastic body toward the first fixed electrode and the second fixed electrode when the operation force is exerted on the pressure receiving part. The insulating layer is electrically insulating. The elastic body includes a first deformable part and a second deformable part on the counter surface. The first deformable part faces at least one of the first fixed electrode or the second fixed electrode via the insulating layer. The first deformable part and the second deformable part is configured to be compressed when the operation force is exerted on the pressure receiving part. At least at a time point at which the operation force is started to be exerted on the pressure receiving part, a ratio of change in an area of the first deformable part is higher than a ratio of change in an area of the second deformable part.

### BRIEF DESCRIPTION OF DRAWINGS

FIG. 1 is a perspective view of an input device according to an embodiment;

FIG. 2 is a sectional view along line II-II of FIG. 1 and shows a state before an operation force is exerted on the input device;

FIG. 3 is a sectional view along line II-II of FIG. 1 and shows a state where the operation force is exerted on the input device;

FIG. 4 is an exploded perspective view of the input device;

FIG. 5 is a perspective view of an elastic body of the input device;

FIG. 6A is a side view of the elastic body of the input device;

FIG. 6B is an enlarged view of a part of FIG. 6A;

FIG. 7 is a view showing a fixed electrode layer overlapping a bottom view of the elastic body of the input device;

FIG. 8 is a perspective view of the fixed electrode layer and a body of the input device; and

FIG. 9 is a characteristic view of the input device and input devices of first and second comparative examples.

### DESCRIPTION OF EMBODIMENTS

An input device according to an embodiment will be described below with reference to the drawings. Note that the embodiment described below is a mere example of various embodiments of the present disclosure. Various modifications may be made to the embodiment described below depending on design or the like as long as the object of the present disclosure is achieved. Moreover, figures described in the following embodiment are schematic views. The ratio of sizes and the ratio of thicknesses of components in the figures do not necessarily reflect actual dimensional ratios.

### EMBODIMENT

### Overview

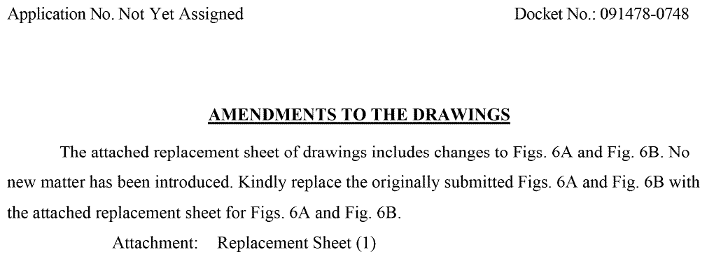

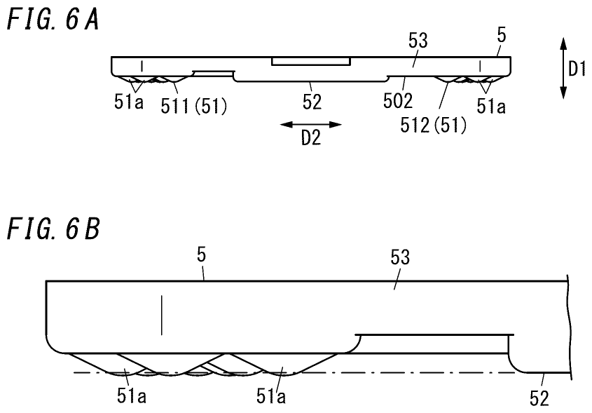

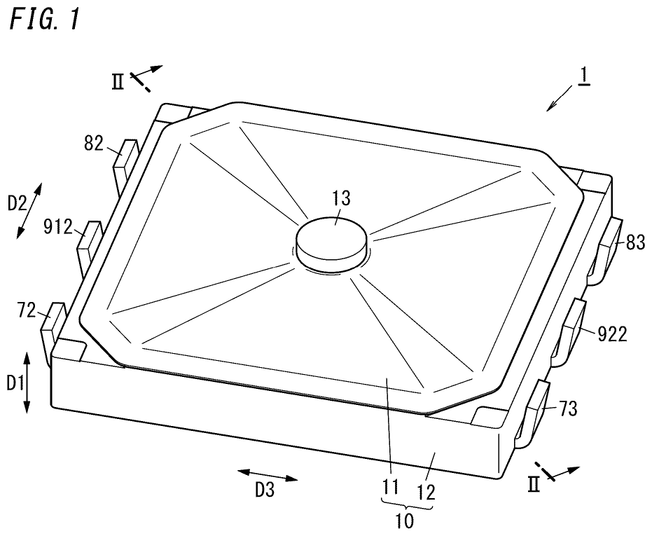

In an input device 1 shown in FIG. 1, capacitance between an elastic body 5 which will be described later and a fixed electrode layer L1 changes depending on a magnitude of an operation force (pressure) exerted on the input device 1. The input device 1 outputs a signal corresponding to the magnitude of the capacitance. In other words, the input device 1 outputs a signal corresponding to the magnitude of the operation force (pressure) exerted on the input device 1. Thus, the input device 1 is used as, for example, a pressure sensor. The signal output from the input device 1 is input to, for example, an electric appliance. The electric appliance operates according to the signal. That is, a user exerts the operation force on the input device 1, thereby operating the electric appliance.

As shown in FIGS. 1 to 4, the input device 1 of the present embodiment includes the fixed electrode layer L1, the elastic body 5, a movable member 2, and an insulating layer 6. The fixed electrode layer L1 includes a first fixed electrode 7 and a second fixed electrode 8 electrically insulated from the first fixed electrode 7. The elastic body 5 is electrically conductive. The elastic body 5 has a counter surface 502 facing the first fixed electrode 7 and the second fixed electrode 8 in a predetermined direction (a first direction D1). The movable member 2 includes a pressure receiving part 311 on which the operation force is to be exerted. The movable member 2 pushes the elastic body 5 toward the first fixed electrode 7 and the second fixed electrode 8 in response to the operation force exerted on the pressure receiving part 311. The insulating layer 6 is electrically insulating. The elastic body 5 includes a first deformable part 51 and a second deformable part 52 on the counter surface 502. The first deformable part 51 faces at least one of the first fixed electrode 7 or the second fixed electrode 8 via the insulating layer 6. When the operation force is exerted on the pressure receiving part 311, the first deformable part 51 and the second deformable part 52 are compressed. At least at a time point at which the operation force is started to be exerted on the pressure receiving part 311, the ratio of change in the area of the first deformable part 51 is higher than the ratio of change in the area of the second deformable part 52. A change in at least one of the area of the first deformable part 51 or the area of the second deformable part 52 changes the capacitance between the elastic body 5 and the fixed electrode layer L1.

According to the present embodiment, the elastic body 5 includes the first deformable part 51 and the second deformable part 52 between which the ratio of change in the area is different. Therefore, as compared with the case where only the first deformable part 51 having a relatively high ratio of change in the area is provided, the capacitance can be suppressed from drastically changing when an operation force is relatively small. Moreover, as compared with the case where only the second deformable part 52 having a relatively low ratio of change in the area is provided, a change in capacitance can be increased.

### (Details)

### (1) Overall Configuration

The input device 1 of the present embodiment will be described below in further detail.

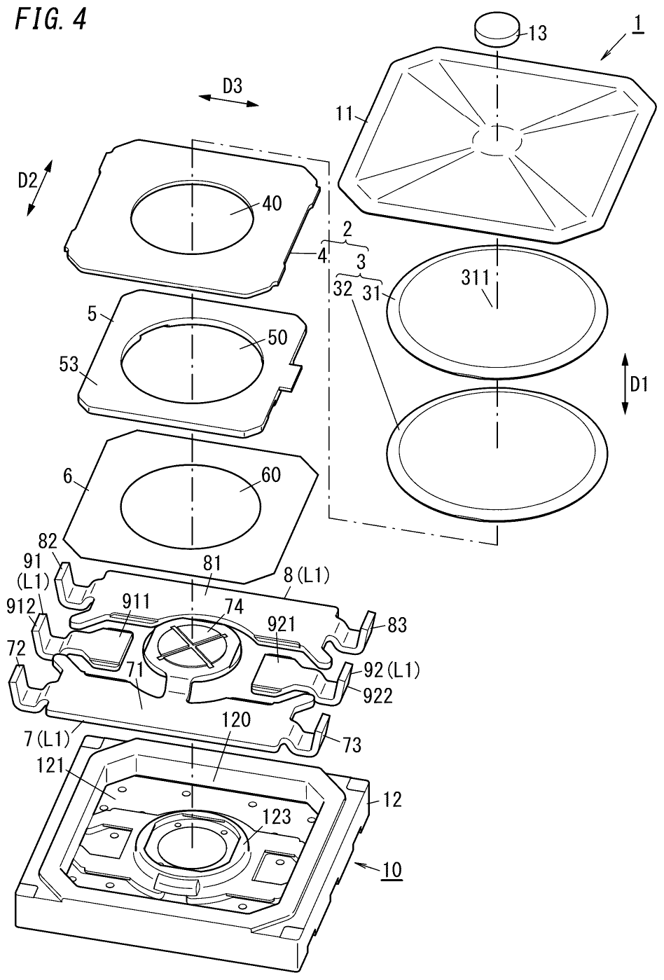

As shown in FIG. 4, the input device 1 includes the fixed electrode layer L1, the elastic body 5, the movable member 2, and the insulating layer 6. The input device 1 further includes a pushing element 13 and a housing 10.

The fixed electrode layer L1 includes the first fixed electrode 7, the second fixed electrode 8, a third fixed electrode 91, and a fourth fixed electrode 92. The movable member 2 includes a clicking member 3 and a movable electrode 4. The housing 10 includes a cover 11 and a body 12.

In the following description, the fixed electrode layer L1 is disposed downward of the movable member 2, and the movable member 2 is disposed upward of the fixed electrode layer L1. However, this definition is not to limit the directions of the input device 1 in use.

The cover 11 is disposed downward of the pushing element 13. The movable member 2 is disposed downward of the cover 11. The elastic body 5 is disposed downward of the movable member 2. The insulating layer 6 is disposed downward of the elastic body 5. Part of the fixed electrode layer L1 is disposed downward of the insulating layer 6.

The first direction D1 in the present disclosure coincides with the up/down direction. Moreover, a second direction D2 in the present disclosure is a direction orthogonal to the first direction D1. A third direction D3 in the present disclosure is a direction orthogonal to both the first direction D1 and the second direction D2.

### (2) Housing

As shown in FIGS. 1 and 4, the housing 10 includes the cover 11 and the body 12. The cover 11 and the body 12 are coupled to each other, and thereby, the housing 10 forms a housing space. The housing 10 houses the fixed electrode layer L1, the elastic body 5, the movable member 2, and the insulating layer 6 in the housing space.

The cover 11 and the body 12 are electrically insulating. The cover 11 and the body 12 are formed from, for example, a synthetic resin as a material.

The body 12 is in the shape of a rectangular parallelepiped. The body 12 has a recess 120 having an opening on one surface (upper surface). The cover 11 is in the shape of a quadrangular (e.g., rectangular) film shape in plan view. The term “rectangle” is a concept that includes a square and an equiangular quadrilateral. The cover 11 is attached to the body 12 to cover the opening of the recess 120 of the body 12.

The body 12 further includes a pedestal part 123. The pedestal part 123 protrudes from a center part of a bottom surface 121 of the recess 120. The pedestal part 123 has a columnar shape.

The cover 11 has an upper surface to which the pushing element 13 is attached. More specifically, the pushing element 13 is attached to a center part of the upper surface of the cover 11. The cover 11 is flexible.

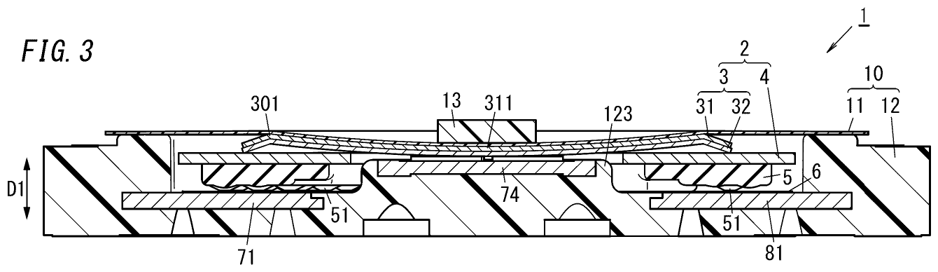

A user pushes the pushing element 13 directly with his/her finger, or via an operation member which is a member brought into contact with the pushing element 13. Thus, the user can exert the operation force on the cover 11 via the pushing element 13. The operation force is directed downward. When the operation force is exerted on the cover 11, the center part of the cover 11 and a center part of the clicking member 3 disposed downward of the cover 11 deform to warp downward as shown in FIG. 3.

### (3) Pushing Element

The pushing element 13 has a columnar shape. The pushing element 13 is electrically insulating.

### (4) Movable Member

As shown in FIG. 4, the movable member 2 includes the clicking member 3 and the movable electrode 4.

The clicking member 3 is sandwiched between the cover 11 and the movable electrode 4. The operation force exerted on the pushing element 13 is transmitted to the movable member 2. The clicking member 3 is elastically deformed by the operation force. The movable electrode 4 is moved downward by the operation force.

The clicking member 3 includes a first plate material 31 and a second plate material 32. The first plate material 31 and the second plate material 32 have a disk shape. The first plate material 31 and the second plate material 32 are stacked one on top of another and are mechanically connected to each other.

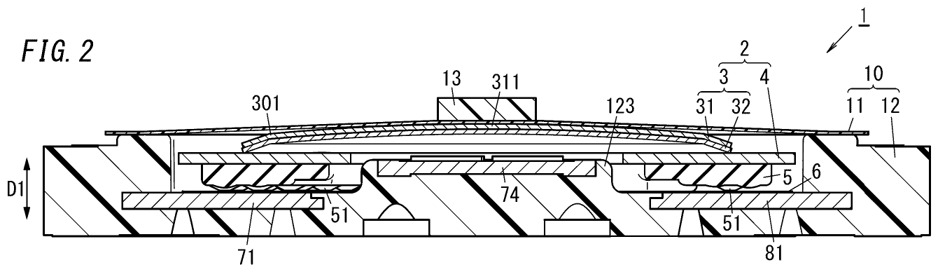

The clicking member 3 is electrically conductive. In the present embodiment, the clicking member 3 is formed from an elastic plate material. The clicking member 3 is formed from, for example, a metal plate such as stainless steel (SUS). The clicking member 3 has a disk shape. The clicking member 3 is a so-called metal dome. As shown in FIG. 2, the clicking member 3 has a dome shape with the center part of the clicking member 3 being convex in a direction away from the movable electrode 4 (upward) while no operation force is exerted on the movable member 2.

Of the clicking member 3, a region along its outer edge is in contact with the movable electrode 4. Thus, the clicking member 3 is electrically connected to the movable electrode 4. Moreover, the clicking member 3 is electrically connected to the elastic body 5 via the movable electrode 4.

Downward of the center part of the clicking member 3, a fixed contact part 74 of the first fixed electrode 7 is disposed. The clicking member 3 faces the fixed contact part 74.

The clicking member 3 includes a pressure receiving part 311 on which the operation force is exerted from the pushing element 13. The pressure receiving part 311 is the center part of the clicking member 3.

In the present embodiment, the clicking member 3 performs inverting operation in accordance with the operation force. Specifically, the clicking member 3 has such a characteristic that until the magnitude of the operation force reaches a predetermined magnitude, a load acting on the pushing element 13 from the clicking member 3 increases, and when the magnitude of the operation force reaches the predetermined magnitude, part (a bending part 301: see FIG. 2) of the clicking member 3 is bent, so that the load acting on the pushing element 13 from the clicking member 3 decreases. This provides a click feeling to the user (operator) who exerts the operation force on the input device 1.

That is, the clicking member 3 further includes the bending part 301. As used in the present disclosure, the “bending part” is a border part between a convex part and a concave part which are formed when the clicking member 3 is bent (inverted) when a force greater than or equal to the predetermined magnitude is exerted on the clicking member 3. As used herein, the “convex part” is an outer peripheral part (a region away from the center) of the clicking member 3 of FIG. 3, and the “concave part” is an area including the center of the clicking member 3 of FIG. 3. In a state where no force is exerted on the clicking member 3, the bending part 301 does not have to be apparently distinguished from the other parts of the clicking member 3.

The bending part 301 is provided around the center part (the pressure receiving part 311) of the clicking member 3. When viewed in the up/down direction, the region occupied by the bending part 301 is a circularly annular region. The bending part 301 are provided to both the first plate material 31 and the second plate material 32.

When the pressure receiving part 311 receives an operation force greater than or equal to the predetermined magnitude, the bending part 301 deforms (is bent), and the clicking member 3 thus warps. As an example, the clicking member 3 deforms to have a dome shape such that the clicking member 3 is convex in a direction in which the center part (the pressure receiving part 311) of the clicking member 3 is separated away from the pushing element 13 (downward) as shown in FIG. 3. Deformation of the bending part 301 as shown in FIG. 3 reduces the load acting on the pushing element 13 from the clicking member 3.

As the result that the bending part 301 is bent, the distance between the clicking member 3 and the fixed contact part 74 of the first fixed electrode 7 changes. More specifically, the pressure receiving part 311 approaches, and comes into contact with, the fixed contact part 74 as the result that the bending part 301 is bent.

Moreover, when the operation force is removed, the clicking member 3 returns to the shape which the clicking member 3 had at a time point before the operation force is exerted thereon. Thus, the pressure receiving part 311 is separated from the fixed contact part 74.

The movable electrode 4 is formed from metal as a material. The movable electrode 4 is electrically conductive. The movable electrode 4 is formed from a plate material. The movable electrode 4 has a frame shape. The movable electrode 4 has a rectangular outer peripheral edge. The movable electrode 4 has a through hole 40 at its center part. The through hole 40 has a circular shape. When viewed from above, the fixed contact part 74 of the first fixed electrode 7 is disposed inside the through hole 40.

The movable electrode 4 is sandwiched between the elastic body 5 and the clicking member 3. When the operation force is exerted on the pressure receiving part 311, the movable electrode 4 pushes the elastic body 5 downward.

The elastic modulus of the movable electrode 4 is greater than the elastic modulus of the elastic body 5.

### (5) Elastic Body

The elastic body 5 is conductive rubber. More specifically, the elastic body 5 is formed by uniformly dispersing conductive particles, such as carbon particles, in rubber which is an insulator.

As shown in FIG. 4, the elastic body 5 has a plate shape as a whole. When viewed in the thickness direction defined with respect to the elastic body 5, the elastic body 5 has a rectangular outer peripheral edge. The elastic body 5 has a through hole 50 at its center part. The through hole 50 has a circular shape. When viewed from above, the fixed contact part 74 of the first fixed electrode 7 is disposed inside the through hole 50.

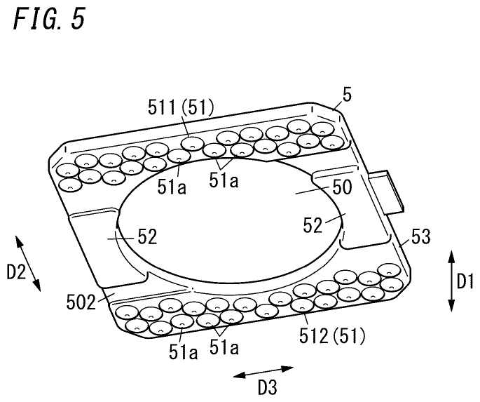

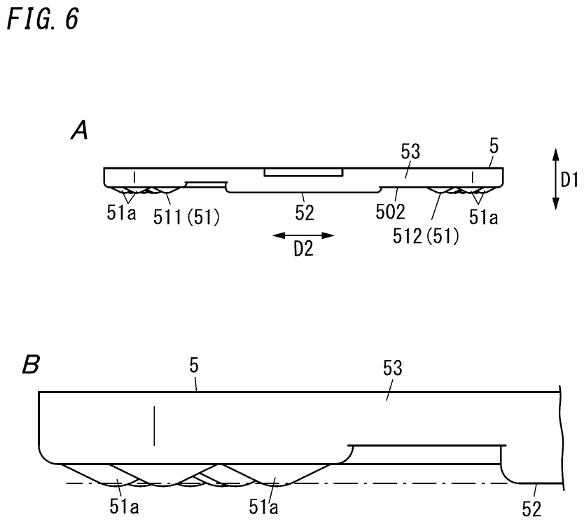

As shown in FIGS. 5 and 6A, the elastic body 5 includes the first deformable part 51, two second deformable parts 52, and a base section 53.

The base section 53 has a plate shape. The base section 53 has a rectangular outer peripheral edge. The first deformable part 51 and the two second deformable parts 52 protrude downward from the base section 53. The base section 53 has an upper surface which is in contact with the movable electrode 4.

The first deformable part 51 is integral with the two second deformable parts 52. More specifically, the first deformable part 51 and the two second deformable parts 52 are connected to be integral via the base section 53. The first deformable part 51, the two second deformable parts 52, and the base section 53 are formed as one inseparable member.

The first deformable part 51 includes a plurality of projections 51a. Each of the plurality of projections 51a is in the shape of a circular truncated cone. The plurality of projections 51a protrude downward from the base section 53. Between the plurality of projections 51a, a gap is provided.

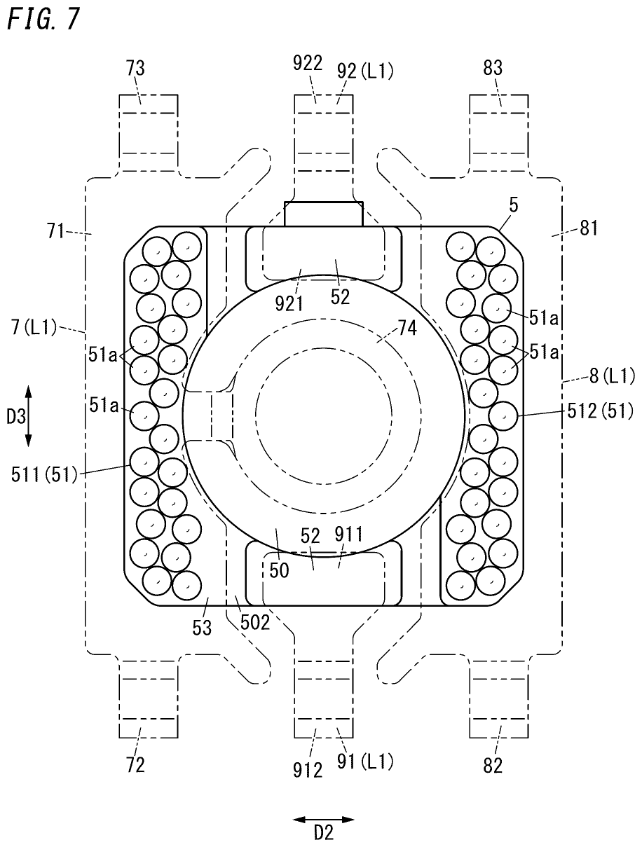

Moreover, the first deformable part 51 includes a first counter part 511 facing the first fixed electrode 7 and a second counter part 512 facing the second fixed electrode 8 (see FIG. 7). The insulating layer 6 is sandwiched between the first counter part 511 and the first fixed electrode 7. The insulating layer 6 is sandwiched between the second counter part 512 and the second fixed electrode 8.

The first counter part 511 and the second counter part 512 are aligned with each other in the second direction D2. Each of the first counter part 511 and the second counter part 512 is provided with the plurality of projections 51a.

Each second deformable part 52 preferably has a columnar or frustrum shape. In the present embodiment, each second deformable part 52 has a columnar shape, and specifically, a prism shape.

The two second deformable parts 52 are disposed between the first counter part 511 and the second counter part 512. The two second deformable parts 52 are aligned with each other in the third direction D3.

One second deformable part 52 of the two second deformable parts 52 faces the third fixed electrode 91, and the insulating layer 6 is sandwiched between the one second deformable part 52 and the third fixed electrode 91. The other second deformable part 52 of the two second deformable parts 52 faces the fourth fixed electrode 92, and the insulating layer 6 is sandwiched between the other second deformable part 52 and the fourth fixed electrode 92.

The through hole 50 in the center part of the elastic body 5 is disposed between the first counter part 511 and the second counter part 512. Moreover, the through hole 50 is disposed between the two second deformable parts 52.

When the operation force is exerted on the pressure receiving part 311 of the movable member 2, the elastic body 5 receives the force from the movable member 2 (the movable electrode 4) and is compressed in the up/down direction. More specifically, the first deformable part 51 is sandwiched between the movable electrode 4 and a set of the first fixed electrode 7 and the second fixed electrode 8 and is compressed. Moreover, one of the two second deformable parts 52 is sandwiched between the third fixed electrode 91 and the movable electrode 4 and is compressed. The other of the two second deformable parts 52 is sandwiched between the fourth fixed electrode 92 and the movable electrode 4 and is compressed.

When the operation force is removed, the elastic body 5 returns to the shape which the elastic body 5 had at a time point before the operation force is exerted thereon.

As shown in FIG. 7, the area where the two second deformable parts 52 faces the first fixed electrode 7 and the second fixed electrode 8 is smaller than the area where the first deformable part 51 faces the first fixed electrode 7 and the second fixed electrode 8. The former is equal to zero. The latter is equal to the area of the first deformable part 51. The area of the first deformable part 51 is the sum of the area of the first counter part 511 and the area of the second counter part 512.

As shown in FIG. 7, the sum of the area where the second deformable part 52 faces the third fixed electrode 91 and the area where the second deformable part 52 faces the fourth fixed electrode 92 is smaller than the area where the first deformable part 51 faces the first fixed electrode 7 and the second fixed electrode 8.

The two second deformable parts 52 are disposed outside a region of the elastic body 5, the region facing the first fixed electrode 7 and the second fixed electrode 8. In other words, the two second deformable parts 52 are disposed at a location in which the two second deformable parts 52 faces neither the first fixed electrode 7 nor the second fixed electrode 8.

Moreover, the area of the first deformable part 51 is greater than the sum of the areas of all (here, two) second deformable parts 52.

### (6) Insulating Layer

The insulating layer 6 shown in FIG. 4 is electrically insulating. The insulating layer 6 has a sheet shape. The insulating layer 6 has a substantially rectangular plate shape. The insulating layer 6 has a through hole 60 at its center part. The through hole 60 has a circular shape. When viewed from above, the fixed contact part 74 of the first fixed electrode 7 is disposed inside the through hole 60.

### (7) Fixed Electrode Layer

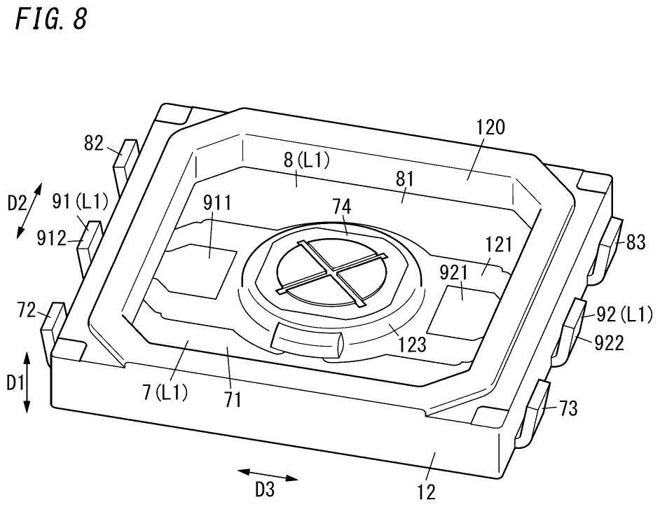

As shown in FIGS. 4, 7, and 8, the fixed electrode layer L1 includes the first fixed electrode 7, the second fixed electrode 8, the third fixed electrode 91, and the fourth fixed electrode 92. Each of the first fixed electrode 7, the second fixed electrode 8, the third fixed electrode 91, and the fourth fixed electrode 92 is formed from a conductive metal plate. The first fixed electrode 7, the second fixed electrode 8, the third fixed electrode 91, and the fourth fixed electrode 92 are electrically insulated from one another. The first fixed electrode 7 and the second fixed electrode 8 output an electric signal according to a change in the capacitance between the first fixed electrode 7 and the elastic body 5 and between the second fixed electrode 8 and the elastic body 5.

The fixed electrode layer L1 is integrated with the body 12 by insert molding. That is, the body 12 is formed by insert molding by using the fixed electrode layer L1 as an insert.

The first fixed electrode 7 and the second fixed electrode 8 are aligned with each other in the second direction D2.

The first fixed electrode 7 includes a first electrode unit 71, a terminal 72, a terminal 73 and the fixed contact part 74.

The first electrode unit 71 faces the first counter part 511 of the elastic body 5 via the insulating layer 6. The first electrode unit 71 extends over both ends of the body 12 in the third direction D3.

The terminal 72, the terminal 73, and the fixed contact part 74 are connected to the first electrode unit 71.

The first electrode unit 71 is exposed from the bottom surface 121 of the recess 120 of the body 12.

The terminal 72 and the terminal 73 penetrate through the body 12 and are exposed outside the body 12.

The fixed contact part 74 is exposed from an upper surface of the pedestal part 123 of the body 12. The fixed contact part 74 is disposed downward of the clicking member 3. The fixed contact part 74 faces the clicking member 3.

The second fixed electrode 8 includes a second electrode unit 81, a terminal 82, and a terminal 83.

The second electrode unit 81 faces the second counter part 512 of the elastic body 5 via the insulating layer 6. The second electrode unit 81 extends over both ends of the body 12 in the third direction D3. The second electrode unit 81 and the first electrode unit 71 are aligned with each other in the second direction D2. The second electrode unit 81 and the first electrode unit 71 are disposed on the same plane.

The second electrode unit 81 is exposed from the bottom surface 121 of the recess 120 of the body 12.

The terminal 82 and the terminal 83 penetrate through the body 12 and are exposed outside the body 12.

The third fixed electrode 91 includes a third electrode unit 911 and a terminal 912. The fourth fixed electrode 92 includes a fourth electrode unit 921 and a terminal 922.

The third electrode unit 911 and the fourth electrode unit 921 are exposed from the bottom surface 121 of the recess 120 of the body 12. The third electrode unit 911 and the fourth electrode unit 921 are aligned with each other in the third direction D3. The third electrode unit 911 faces one second deformable part 52 of the two second deformable parts 52 of the elastic body 5 via the insulating layer 6. The fourth electrode unit 921 faces the other second deformable part 52 via the insulating layer 6. The first electrode unit 71, the second electrode unit 81, the third electrode unit 911, and the fourth electrode unit 921 are disposed on the same plane.

The terminal 912 is connected to the third electrode unit 911. The terminal 922 is connected to the fourth electrode unit 921. The terminal 912 and the terminal 922 penetrate through the body 12 and are exposed outside the body 12.

The terminals 72, 73, 82, 83, 912, and 922 are mechanically coupled to, and electrically connected to, for example, a conductive member on a printed circuit board by soldering.

Via the terminals 72, 73, 82, and 83, the capacitance is measured. The terminals 912 and 922 are dummy terminals.

### (8) Operation Example

Next, an operation example of the input device 1 will be described with reference to, for example, FIGS. 2 and 3.

When the operation force is exerted on the pushing element 13, the operation force is transmitted to the pressure receiving part 311 of the movable member 2. Then, the movable electrode 4 of the movable member 2 moves downward. Moreover, the elastic body 5 is pushed downward by the movable electrode 4. The elastic body 5 is sandwiched between the fixed electrode layer L1 and the movable electrode 4 and is compressed. Thus, the elastic body 5 elastically deforms, thereby increasing the area where the elastic body 5 and the fixed electrode layer L1 face each other, and therefore, the capacitance between the elastic body 5 and the fixed electrode layer L1 increases. The capacitance between the elastic body 5 and the fixed electrode layer L1 at this time is more specifically a composite capacitance of the capacitance between the first counter part 511 and the first fixed electrode 7 and the capacitance between the second counter part 512 and the second fixed electrode 8.

Moreover, when the pressure receiving part 311 receives an operation force greater than or equal to the predetermined magnitude, the bending part 301 deforms (is bent), the clicking member 3 warps, and the clicking member 3 comes into contact with, and is thus electrically connected to, the fixed contact part 74. Thus, the capacitance between the elastic body 5 and the fixed electrode layer L1 drastically changes. The capacitance between the elastic body 5 and the fixed electrode layer L1 at this time is more specifically the capacitance between the second counter part 512 and the second fixed electrode 8.

When the state where the operation force is exerted on the input device 1 transitions to the state where no operation force is exerted on the input device 1, the elastic body 5 and the clicking member 3 elastically return, and thereby, each component of the input device 1 returns to the same location and shape as in the state where no operation force is exerted on the input device 1, and the capacitance also returns to initial capacitance.

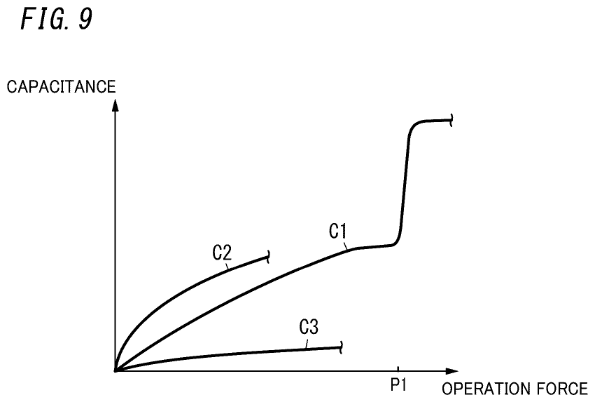

In FIG. 9, a curved line C1 shows the relationship between the magnitude of the operation force and the capacitance in the input device 1 of the present embodiment. An operation force P1 represents an operation force of the “predetermined magnitude”.

Moreover, in FIG. 9, a curved line C2 shows the relationship between the magnitude of the operation force and the capacitance in an input device of a first comparative example. The input device of the first comparative example is different from the input device 1 of the present embodiment in that the input device of the first comparative example does not include the two second deformable parts 52 but includes projections 51a disposed on the entire lower surface of an elastic body 5. At a time point at which the operation force is started to be exerted on the input device 1, the ratio of change in the area of each projection 51a is higher than the ratio of change in the area of the second deformable part 52. Therefore, in the first comparative example, the capacitance drastically increases. Thus, in a range in which the operation force is relatively large, there may be a case where the projections 51a have already been compressed to their limits, and the area of a first deformable part 51 does not change, and therefore, a change in the capacitance cannot be sensed. Moreover, there is the problem that the linearity of the operation force and the capacitance is poor.

In FIG. 9, a curved line C3 shows the relationship between the magnitude of the operation force and the capacitance in an input device of a second comparative example. Here, of the input device 1 of the present embodiment, a region in which the first deformable part 51 is disposed is referred to as a specific region. The input device of the second comparative example includes second deformable parts 52 at the same locations as in the input device 1 of the present embodiment. In contrast, the input device of the second comparative example is different from the input device 1 of the present embodiment in that the input device of the second comparative example does not include the first deformable part 51 (the plurality of projections 51a) but includes the second deformable parts 52 disposed also in the specific region. Therefore, in the second comparative example, a change in the capacitance in response to the operation force is small. Thus, sensitivity to the operation force may be insufficient.

Therefore, the input device 1 of the present embodiment includes both the first deformable part 51 and the second deformable part 52. At a time point at which the operation force is started to be exerted, the first deformable part 51 mainly deforms and increases the area, but the presence of the second deformable parts 52 which relatively resistant to deformation can suppress the area of the first deformable part 51 from drastically increasing. This can improve the linearity of the operation force and the capacitance. Moreover, a change in capacitance is large as compared with the case where only the second deformable part 52 is provided.

Thus, the input device 1 of the present embodiment can improve the linearity of the operation force and the capacitance and improve the sensitivity to the operation force while a maximum value of a detectable operation force as the capacitance is increased.

In the input device 1 of the present embodiment, only the first deformable part 51 out of a group consisting of the first deformable part 51 and the two second deformable parts 52 faces the first fixed electrode 7 and the second fixed electrode 8. Therefore, a contribution of the two second deformable parts 52 to the capacitance is small. The two second deformable parts 52 are disposed to adjust the deformation amount of the first deformable part 51 with respect to the magnitude of the operation force.

Here, in the predetermined direction (first direction D1), the distance (first distance) between the first deformable part 51 of the elastic body 5 (see FIG. 6A) and the fixed electrode layer L1 is shorter than the distance (second distance) between the second deformable part 52 and the fixed electrode layer L1. More specifically, the first distance is defined by the distance between a tip end of each projection 51a of the first deformable part 51 and the first electrode unit 71 of the fixed electrode layer L1. Moreover, the second distance is defined by the distance between a lower surface of the second deformable part 52 and the second electrode unit 81 of the fixed electrode layer L1.

As shown in FIG. 6B, the tip end of each projection 51a protrudes downward slightly beyond the lower surface of the second deformable part 52. Moreover, the first electrode unit 71 and the second electrode unit 81 are present on the same plane. Therefore, the first distance is shorter than the second distance.

Since the first distance is shorter than the second distance, the first deformable part 51 is compressed before the second deformable part 52. Thus, the magnitude of the capacitance at the time point at which the operation force is started to be exerted can be secured to a certain extent.

As an example, the length of each projection 51a in the first direction D1 is preferably five or more times and fifteen or less times the difference between the first distance and the second distance. As an example, the length of the projection 51a in the first direction D1 is 50 to 60 μm. As an example, the difference between the first distance and the second distance is 5 to 10 μm.

### VARIATIONS OF EMBODIMENT

Variations of the embodiment will be enumerated below. The variations described below may be accordingly combined with each other.

The shape of the projections 51a of the first deformable part 51 is not limited to the shape of a circular truncated cone. For example, each projection 51a may have a frustrum shape, a pyramid shape, a columnar shape, or a semispherical shape.

The projection 51a may have a hollow therein. Thus, the projection 51a is easily deformed by compression.

It is only required that the first deformable part 51 has a higher ratio of change in the area than the second deformable part 52 at a time point at which the operation force is started to be exerted on the pressure receiving part 311, and the first deformable part 51 does not have to include the plurality of projections 51a. For example, the first deformable part 51 may have a hollow columnar or frustrum shape having, whereas the second deformable part 52 may have a solid (i.e., not hollow) columnar or frustrum shape.

The first deformable part 51 of the embodiment is separated into the first counter part 511 and the second counter part 512. In contrast, the first deformable part 51 may be collectively provided at one location or may be distributed at three or more locations.

The number of second deformable parts 52 is not limited to two. One second deformable part 52 or three or more second deformable parts 52 may be disposed. For example, the second deformable parts 52 may be disposed at four corners of the elastic body 5 when viewed from below.

The second deformable part 52 of the embodiment is sandwiched between the fixed electrode layer L1 and the movable electrode 4 and is compressed. In contrast, the second deformable part 52 may be sandwiched between the bottom surface 121 of the recess 120 of the body 12 and the movable electrode 4 and is compressed. That is, the second deformable part 52 does not have to face the fixed electrode layer L1.

One of the first fixed electrode 7 and the second fixed electrode 8 does not have to face the first deformable part 51. The one of the first fixed electrode 7 and the second fixed electrode 8 may face, for example, the second deformable part 52. Also in this case, the capacitance of the fixed electrode facing the first deformable part 51 can be suppressed from drastically changing when an operation force is relatively small.

The clicking member 3 of the embodiment includes two plate materials, that is, the first plate material 31 and the second plate material 32, stacked one on top of another. Note that the clicking member 3 may include one plate material or three or more plate materials.

Since the third fixed electrode 91 and the fourth fixed electrode 92 are dummy electrodes, the input device 1 does not have to include the third fixed electrode 91 and the fourth fixed electrode 92.

Alternatively, the operation force is exerted on the pressure receiving part 311 of the movable member 2, and the movable member 2 is thus moved or deformed, and thereby, the third fixed electrode 91 and the fourth fixed electrode 92 may be electrically connected to each other via the movable member 2. Thus, the terminals 912 and 922 are electrically connected, and therefore, a circuit electrically connected to the terminals 912 and 922 can sense, for example, that the movable member 2 has moved to a predetermined location.

The insulating layer 6 between the fixed electrode layer L1 and the elastic body 5 is not limited to being formed from the insulating sheet. The insulating layer 6 may be formed from, for example, air. That is, the input device 1 may include a structure for regulating the positional relationship between the fixed electrode layer L1 and the elastic body 5 such that an air gap is formed between the fixed electrode layer L1 and the elastic body 5.

The pushing element 13 may be disposed between the cover 11 and the movable member 2.

The movable member 2 includes the clicking member 3 but does not have to have the movable electrode 4. In this case, the clicking member 3 comes into contact with the elastic body 5 so that the clicking member 3 is electrically connected to the elastic body 5 without using the movable electrode 4.

The input device 1 is not limited to being used to operate various electronic apparatuses but may be used to sense locations of apparatuses, for example. When an apparatus moves to a predetermined location, the apparatus exerts an operation force on the input device 1 installed at the predetermined location, and the operation force is detected as a change in capacitance of the input device 1.

### SUMMARY

From the embodiment and the like described above, the following aspects are disclosed.

An input device (1) of a first aspect includes a fixed electrode layer (L1), an elastic body (5), a movable member (2), and am insulating layer (6). The fixed electrode layer (L1) includes a first fixed electrode (7) and a second fixed electrode (8) electrically insulated from the first fixed electrode (7). The elastic body (5) is electrically conductive. The elastic body (5) has a counter surface (502) facing the first fixed electrode (7) and the second fixed electrode (8) in a predetermined direction. The movable member (2) includes a pressure receiving part (311) on which an operation force is to be exerted. The movable member (2) is configured to push the elastic body (5) toward the first fixed electrode (7) and the second fixed electrode (8) when the operation force is exerted on the pressure receiving part (311). The insulating layer (6) is electrically insulating. The elastic body (5) includes a first deformable part (51) and at least one second deformable part (52) on the counter surface (502). The first deformable part (51) faces at least one of the first fixed electrode (7) or the second fixed electrode (8) via the insulating layer (6). The first deformable part (51) and the at least one second deformable part (52) are configured to be compressed when the operation force is exerted on the pressure receiving part (311). At least at a time point at which the operation force is started to be exerted on the pressure receiving part (311), a ratio of change in an area of the first deformable part (51) is higher than a ratio of change in an area of the at least one second deformable part (52).

With this configuration, the elastic body (5) includes the first deformable part (51) and the at least one second deformable part (52) between which the ratio of change in the area is different. Therefore, as compared with the case where only the first deformable part (51) having a relatively high ratio of change in the area is provided, the capacitance can be suppressed from drastically changing when an operation force is relatively small. Moreover, as compared with the case where only the at least one second deformable part (52) having a relatively low ratio of change in the area is provided, a change in the capacitance between the elastic body (5) and the fixed electrode layer (L1) can be increased.

In an input device (1) of a second aspect referring to the first aspect, an area where the at least one second deformable part (52) faces the first fixed electrode (7) and the second fixed electrode (8) is smaller than an area where the first deformable part (51) faces the first fixed electrode (7) and the second fixed electrode (8).

With this configuration, the capacitance detected by the input device (1) can be correlated mainly with the deformation amount of the first deformable part (51).

In an input device (1) of a third aspect referring to the second aspect, the at least one second deformable part (52) is disposed outside a region of the elastic body (5), the region facing the first fixed electrode (7) and the second fixed electrode (8).

With this configuration, the capacitance detected by the input device (1) can be correlated mainly with the deformation amount of the first deformable part (51).

In an input device (1) of a fourth aspect referring to any one of the first to third aspects, the first deformable part (51) includes a plurality of projections (51a).

This configuration enables the ratio of change in the area of the first deformable part (51) to be increased.

In an input device (1) of a fifth aspect referring to any one of the first to fourth aspects, the at least one second deformable part (52) has a columnar or frustrum shape.

This configuration enables the ratio of change in the area of the at least one second deformable part (52) to be suppressed.

In an input device (1) of a sixth aspect referring to any one of the first to fifth aspects, a distance between the first deformable part (51) and the fixed electrode layer (L1) is shorter than a distance between the at least one second deformable part (52) and the fixed electrode layer (L1) in the predetermined direction.

With this configuration, at a time point at which the operation force is started to be exerted, the first deformable part (51) is compressed before the second deformable part (52), and therefore, the magnitude of the capacitance can be secured to a certain degree.

In an input device (1) of a seventh aspect referring to any one of the first to sixth aspects, the first fixed electrode (7) and the second fixed electrode (8) are aligned with each other in a second direction (D2). The second direction (D2) is orthogonal to a first direction (D1) as the predetermined direction. The first deformable part (51) includes a first counter part (511) facing the first fixed electrode (7) and a second counter part (512) facing the second fixed electrode (8).

This configuration enables the area where the first deformable part (51) faces the first fixed electrode (7) and the second fixed electrode (8) to be secured to a certain extent.

In an input device (1) of an eighth aspect referring to the seventh aspect, the at least one second deformable part (52) included in the elastic body (5) includes two second deformable parts (52). The two second deformable parts (52) are disposed between the first counter part (511) and the second counter part (512). The two second deformable parts (52) are aligned with each other in a third direction (D3) orthogonal to both the first direction (D1) and the second direction (D2).

With this configuration, the two second deformable parts (52) can support the elastic body (5).

In an input device (1) of a ninth aspect referring to any one of the first to eighth aspects, the first deformable part (51) is integral with the at least one second deformable part (52).

This configuration reduces the number of components as compared with the case where the first deformable part (51) and the second deformable part (52) are separated.

The configurations other than the configuration of the first aspect are not configurations essential for the input device (1) and may thus accordingly be omitted.

### REFERENCE SIGNS LIST

1 Input Device
2 Movable Member
5 Elastic Body
6 Insulating Layer
7 First Fixed Electrode
8 Second Fixed Electrode
51 First Deformable Part
51a Projection
52 Second Deformable Part
311 Pressure Receiving Part
502 Counter Surface
511 First Counter Part
512 Second Counter Part
D1 First Direction
D2 Second Direction
D3 Third Direction
L1 Fixed Electrode Layer

1. An input device comprising:
a fixed electrode layer including
a first fixed electrode and
a second fixed electrode electrically insulated from the first fixed electrode;
an elastic body being conductive and having a counter surface facing the first fixed electrode and the second fixed electrode in a predetermined direction;
a movable member including a pressure receiving part on which an operation force is to be exerted and configured to push the elastic body toward the first fixed electrode and the second fixed electrode when the operation force is exerted on the pressure receiving part; and
an insulating layer being electrically insulating,
the elastic body including a first deformable part and at least one second deformable part on the counter surface,
the first deformable part facing at least one of the first fixed electrode or the second fixed electrode via the insulating layer,
the first deformable part and the at least one second deformable part being configured to be compressed when the operation force is exerted on the pressure receiving part,
at least at a time point at which the operation force is started to be exerted on the pressure receiving part, a ratio of change in an area of the first deformable part being higher than a ratio of change in an area of the at least one second deformable part.

2. The input device of claim 1, wherein
an area where the at least one second deformable part faces the first fixed electrode and the second fixed electrode is smaller than an area where the first deformable part faces the first fixed electrode and the second fixed electrode.

3. The input device of claim 2, wherein
the at least one second deformable part is disposed outside a region of the elastic body, the region facing the first fixed electrode and the second fixed electrode.

4. The input device of claim 1, wherein
the first deformable part includes a plurality of projections.

5. The input device of claim 1, wherein
the at least one second deformable part has a columnar or frustrum shape.

6. The input device of claim 1, wherein
a distance between the first deformable part and the fixed electrode layer is shorter than a distance between the at least one second deformable part and the fixed electrode layer in the predetermined direction.

7. The input device of claim 1, wherein
the first fixed electrode and the second fixed electrode are aligned with each other in a second direction orthogonal to a first direction as the predetermined direction, and
the first deformable part includes a first counter part facing the first fixed electrode and a second counter part facing the second fixed electrode.

8. The input device of claim 7, wherein
the at least one second deformable part included in the elastic body includes two second deformable parts,
the two second deformable parts are disposed between the first counter part and the second counter part, and
the two second deformable parts are aligned with each other in a third direction orthogonal to both the first direction and the second direction.

9. The input device of claim 1, wherein
the first deformable part is integral with the at least one second deformable part.
